(19) United States
(12) Patent Application Publication
(10) Pub. No.: US 2019/0062943 A1
(43) Pub. Date: Feb. 28, 2019

(54) DEVITRIFICATION AGENT FOR QUARTZ GLASS CRUCIBLE CRYSTAL GROWING PROCESS

(71) Applicant: MOMENTIVE PERFORMANCE MATERIALS INC., Waterford, NY (US)

(72) Inventor: Richard Lee Hansen, Mentor, OH (US)

(21) Appl. No.: 16/086,756

(22) PCT Filed: Mar. 10, 2017
(86) PCT No.: PCT/US2017/021712

§ 371 Date: Sep. 20, 2018

Related U.S. Application Data
(60) Provisional application No. 62/312,019, filed on Mar. 23, 2016.

(51) Int. Cl. C30B 15/10; C30B 29/06; C30B 35/00; C03C 10/00

(52) U.S. Cl. CPC C30B 15/10; C03C 10/0009; C30B 35/002; C30B 29/06

(57) ABSTRACT

The present technology provides a devitrification agent for crucibles with improved efficiency over previous devitrification agents for use in various technological fields, including semiconductors and photovoltaic applications. The devitrification agent may include (a) barium, and (b) tantalum, tungsten, germanium, tin, or a combination of two or more thereof. The devitrification agent may be integrated into a crucible during construction, applied to the surface of a finished crucible, and/or added into the silicon melt used in crystal pull. The technology described herein, improves sag resistance and provides a devitrified surface for slower, more controlled dissolution of silica by liquid silicon melt during silicon crystal growth.

### CROSS-REFERENCE TO RELATED APPLICATIONS

The present application claims priority to and the benefit of U.S. Provisional Application No. 62/312,019 titled “Devitrification Agent for Quartz Glass Crucible Crystal Growing Process,” filed on Mar. 23, 2016, the disclosure of which is incorporated herein by reference in its entirety.

### FIELD

The present technology relates to quartz glass articles, including quartz glass crucibles used for pulling a silicon single crystal and methods for treating quartz glass articles for use in crystal growing processes.

### BACKGROUND

Single crystal silicon which is the starting material for most processes for the fabrication of semiconductor electronic components is commonly prepared with the so-called Czochralski (“Cz”) process. In this process, polycrystalline silicon (“polysilicon”) is charged to a crucible, the polysilicon is melted, a seed crystal is immersed into the molten silicon and a single crystal silicon ingot is grown by slow extraction.

The crucible of choice for use in the Cz process is commonly referred to as a fused quartz crucible or simply a quartz crucible and is composed of an amorphous form of silica known as vitreous silica. One disadvantage associated with the use of vitreous silica, however, is the fact that contaminants on the inner surface of the crucible can nucleate and promote the formation of cristobalite islands in the vitreous silica surface (the islands being centered, in general, about the contamination site) as the polysilicon is melted and the single crystal ingot is grown. The cristobalite islands can be undercut and fragments released as particles into the silicon melt, causing the formation of dislocations in the silicon ingot.

Recently, the use of devitrification agents is more widespread for application to crucibles used to grow crystals for semiconductors and photo-voltaics through the Cz crystal growing process. However, some demanding applications for semi-conductors are sensitive to side effects of the inorganic compounds typically used, e.g., cations such as Ca, Sr, and Ba.

### SUMMARY

The present technology provides a devitrification agent for crucibles with improved efficiency over previous devitrification agents. The technology described herein improves the properties of the crucible including sag resistance and provides a devitrified surface for slower, more controlled dissolution of silica by liquid silicon melt during silicon crystal growth. The technology may be used in various technological fields, including, but not limited to, semiconductors and photovoltaic applications.

In one aspect, the present technology provides a crucible comprising a body of vitreous silica having a bottom wall and a sidewall extending up from the bottom wall and defining a cavity for holding the molten silicon material, the sidewall formation and the bottom wall each having an inner and an outer surface, the crucible comprising a devitrification agent comprising (a) a first metal chosen from barium and (b) a second metal chosen from tantalum, tungsten, germanium, tin, or a combination of two or more thereof

In one embodiment, the devitrification agent has a ratio of first metal to second metal of from about 1:1 to about 10:1, from about 2:1 to about 8:1 and even from about 5:2 to about 6:1.

In one embodiment, the devitrification agent is disposed as a coating on at least a portion of a surface of the crucible.

In one embodiment, the coating comprises the first metal in the form of an alkoxide, a hydroxide, a carbonate, a sol-gel solution, or a combination of two or more thereof, and the second metal in the form an alkoxide, a hydroxide, a carbonate, a sol-gel solution, or a combination of two or more thereof.

In one embodiment, the devitrification agent further comprises a barium halide.

In one embodiment, the devitrification agent is disposed in the crucible body.

In one embodiment, the devitrification agent comprises (a) barium oxide, and (b) tantalum oxide, tungsten oxide, germanium oxide, tin oxide, or a combination of two or more thereof.

In one aspect, the present technology provides a method for preparing a silicon melt for pulling a single crystal, such as, for example, by the Czochralski method, the method comprising providing a silicon to a crucible comprising a body of vitreous silica having a bottom wall and a sidewall extending up from the bottom wall and defining a cavity for holding the molten silicon material, the sidewall formation and the bottom wall each having an inner and an outer surface, the crucible comprising a devitrification agent comprising (a) a first metal chosen from barium and (b) a second metal chosen from tantalum, tungsten, germanium, tin, or a combination of two or more thereof and melting the silicon within the crucible to form a first layer of substantially devitrified silica on the inner surface of the crucible which is in contact with the molten silicon.

In one embodiment, the devitrification agent has a ratio of first metal to second metal of from about 1:1 to about 10:1; from about 2:1 to about 8:1, even from about 5:2 to about 6:1.

In one embodiment, the devitrification agent is disposed as a coating on at least a portion of a surface of the crucible.

In one embodiment, the coating comprises the first metal in the form of an alkoxide, a hydroxide, a carbonate, a sol-gel solution, or a combination of two or more thereof, and the second metal in the form an alkoxide, a hydroxide, a carbonate, a sol-gel solution, or a combination of two or more thereof.

In one embodiment, the devitrification agent further comprises a barium halide.

In one embodiment, the devitrification agent is disposed in the silicon melt. In one embodiment, the devitrification agent is dispersed in the silicon melt. In another embodiment, the devitrification agent is doped in the silicon melt.

In one embodiment, the devitrification agent comprises (a) barium oxide, barium metal, an alloy compound comprising barium, or a combination of two or more thereof, and (b) the second metal in the form of a metal oxide, metal compound, an alloy compound comprising the second metal, or a combination of two or more thereof.

In one embodiment, the devitrification agent is disposed in the crucible body.

In one embodiment, the devitrification agent comprises (a) barium oxide, and (b) tantalum oxide, tungsten oxide, germanium oxide, tin oxide, or a combination of two or more thereof

In one aspect, the present technology provides a method for making a silica crucible comprising feeding bulk silica grain along an inner surface of a rotating mold to arrange the bulk silica grain in a crucible shape, feeding a devitrification agent-doped silica grain onto the intermediate glass layer, wherein the devitrification agent comprises barium and tantalum, tungsten, germanium, tin, or a combination of the first agent and two or more of the latter agents thereof.

### BRIEF DESCRIPTION OF THE DRAWINGS

FIG. 1 is a schematic vertical section of a crucible of the present technology; and

FIG. 2 is a graph showing effective sag resistance achieved with different types of devitrification promoters.

### DETAILED DESCRIPTION

The present technology provides a devitrification agent for crucibles used in crystal pulling processes. The technology described herein, may provide improved properties, including improved sag resistance, a devitrified surface for slower, more controlled dissolution of silica by liquid silicon melt during silicon crystal growth, etc. Devitrification promoters in accordance with aspects of the present technology may provide a more efficient devitrification promoter in terms of improved properties when used at comparable equivalent concentrations of conventional devitrification promoters, or comparable properties when used at lower equivalent concentrations than conventional devitrification promoters. The technology may be used in various technological fields, including, but not limited to, semiconductors and photovoltaic applications.

As used herein, the term “treated” or “coated” may be used interchangeably to refer to treating the crucible surface with the coating of the technology, leaving substantially all of the quartz glass crucible surface (to be in contact with the silicon melt) substantially in either a fully reduced, partially reduced, partially oxidized or fully oxidized state.

As used herein, the terms “first,” “second,” and the like do not denote any order or importance, but rather are used to distinguish one element from another, and the terms “the”, “a” and “an” do not denote a limitation of quantity, but rather denote the presence of at least one of the referenced item. Furthermore, all ranges disclosed herein are inclusive of the endpoints and are independently combinable.

As used herein, approximating language may be applied to modify any quantitative representation that may vary without resulting in a change in the basic function to which it is related. Accordingly, a value modified by a term or terms, such as “about” and “substantially,” may not to be limited to the precise value specified, in some cases.

As used herein, “quartz glass articles” may be used interchangeably with “quartz glass crucibles,” “quartz crucibles,” “fused quartz crucibles,” “quartz crucible,” and “crucible” referring to glass articles that maybe subjected for extended period of time to high mechanical, chemical, and thermal stress, and if used for crystal pulling, exposed to molten silicon.

As used herein, the term “substantially continuous” refers to continuity with or without insignificant breaks.

As used herein, the term “crystalline morphology” may be used interchangeably with “crystalline growth structure.” The definition of morphology, as known in the art, can be defined at a macroscopic or microscopic level. In one embodiment, “crystalline morphology” refers to a region where the glassy (amorphous) SiO₂ has crystallized into one or more of the several crystalline phases of SiO₂, e.g., crystobalite, tridymite, quartz, etc. These phases may appear or present themselves in different macroscopic structures or shapes. At the microscopic level, the term is defined by the actual crystallite growth faces presented, e.g., crystallite may be presented by, but are not limited to, 1-0-0, 0-1-0, 0-0-1, 1-1-1, 1-1-0, 0-1-1, and 1-0-1 oriented growth faces. These are merely examples of suitable growth faces. It will be appreciated that tridymite and quartz have different crystalline structures from Crystobalite and thus different crystalline growth faces.

As used herein, the term “crystalline surface structures” refers to any and all crystalline phases of SiO₂, including or not limited to crystobalite, quartz alpha, quartz beta, tridymite, and others.

The present technology provides a method and articles for growing crystals including single crystal silicon. The method and articles employ a system that introduces a combination of barium and other metals such as tantalum, tungsten, germanium, and/or tin into the crystal growing process. In accordance with the present technology, the process comprises providing a combination of (a) first metal chosen from barium and (b) a second metal chosen from tantalum, tungsten, germanium, tin, or a combination of two or more thereof to the crucible for use during a crystal growing process. It has been found that the combination of (a) a first metal chosen from barium, and (b) a second metal chosen from tantalum, tungsten, germanium, tin, or a combination of two or more thereof function efficiently as a devitrification promoter in the crystal pulling process. The combination of barium with tantalum, tungsten, tin, and/or germanium is referred to collectively as the devitrification agent, devitrification promoter, or devitrification system.

In one embodiment, the devitrification agent is provided so as to provide a ratio of first metal (barium) to total second metal of from about 1:1 to about 10:1, about 2:1 to about 9:1, even from about 5:2 to about 6:1. Any combination of the first and second metal(s) can be provided to provide a desired ratio of barium:tantalum, barium:tungsten, barium:germanium, barium:tin barium:(tantalum+tungsten), barium: (tantalum+germanium), barium: (tungsten +germanium), barium: (tantalum+tin), barium (tungsten+tin), barium: (germanium+tin), barium: (tantalum+tungsten+germanium), barium (tantalum+germanium+tin), barium: (tantalum+tungsten+tin), or barium: (tantalum+tungsten+germanium+tin). It will be appreciated that the ratios include all whole and fractional variants of such ratios. Here as elsewhere in the specification and claims, numerical values can be combined to form new and non-disclosed ranges. The ratios of the metals are at least approximately that defined by the specific phase compounds in each of the binary, ternary or quaternary phase diagrams of the appropriate components. It may also be appropriate to look at the oxide system phase diagrams, or potentially appropriate non-oxide system phase diagrams.

The devitrification agent can be provided to the crucible in any manner as desired for a particular purpose or intended application. In one embodiment, the devitrification agent comprising the barium and tantalum, tungsten, tin, and/or germanium can be provided as a coating on the inner and/or outer surfaces of the crucible. In another embodiment, the devitrification agent can be provided to the crucible as part of the silicon melt. For example, the devitrification agents can be added to the polysilicon in the crucible before meltdown is initiated. In another example, the devitrification agents can be added to the already melted silicon melt pool as dopants through a doping port in the crystal puller. In adding the devitrification agent to the already melted silicon melt pool, some melt stirring will need to take place. In still another embodiment, the crucible can be bulk doped with the barium and tantalum, tin, germanium, and/or tungsten components of the devitrification agent. It will also be appreciated that the devitrification system can be provided by a combination of two or more of these arrangements. The manner for introducing the components of the devitrification system to the crucible for processing may vary depending on how the devitrification system is being applied or utilized. For example, the materials used to introduce the devitrification components to the crucible may differ when the devitrification system is applied as a coating as compared to when the devitrification system is introduced into the silicon melt or is bulk doped into the crucible.

### Coating Layer

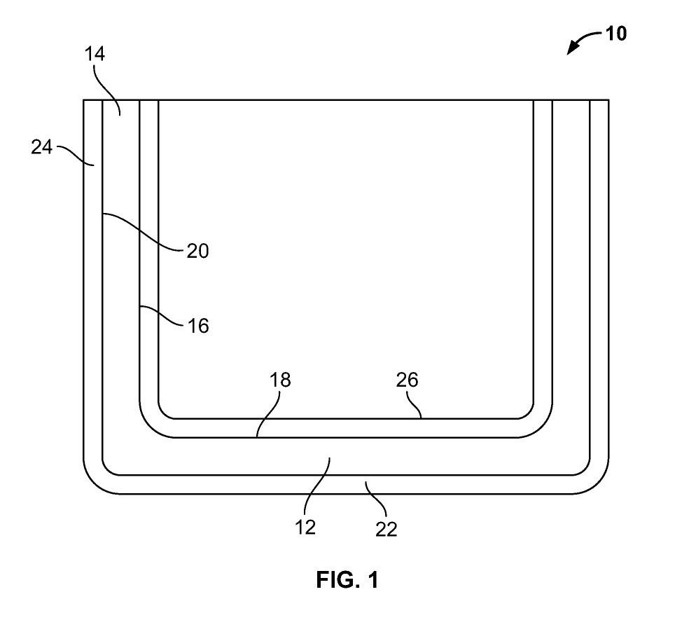

In one embodiment, the devitrification promoter system is applied as a coating layer to a surface of the crucible. The devitrification promoter system can be applied to the inner surface of a crucible, the outer surface of the crucible, or both the inner surface and the outer surface of the crucible. As shown in FIG. 1, a crucible 10 may have a bottom wall 12 and a sidewall 14 extending up from the bottom wall 12 and defining a cavity for holding a material such as the silicon melt. The sidewall 14 has an inner surface 16 and an outer surface 20. The bottom wall 12 has an inner surface 18 and an outer surface 22. An external coating 24 may overlay the sidewall outer surface 20 and the external coating 24 may form a layer having a high density of nucleation sites which surround the outer surface 20 of the sidewall 14. An internal coating 26 may overlay the inner surfaces 16 and 18. The internal coating 26 may form a layer having a high density of nucleation sites covering the interior of the crucible 10. The internal and external coatings 24 and 26 may comprise the devitrification system. It is not necessary that the coating as applied onto either the inner surface or the outer surface be physically continuous in a lateral direction. Rather, the devitrification agent need only be applied to the surface in a manner such that the extent of nucleation of the devitrification is sufficient to cause the devitrification growths to grow together before the actual crystal growing stage is started. It may be desirable for this to occur by the end of the melt down, before the cooling approach to the seed “dip-in” temperature.

In one embodiment, the devitrification system comprises (a) barium, and (b) tantalum, tungsten, germanium, tin, or a combination of two or more thereof. The barium, and tantalum, germanium, tin, and/or tungsten may be provided in the appropriate ratios as part of a solution for application onto the surface of the crucible. The barium, and tantalum, germanium, tin, and/or tungsten may be provided in an appropriate species in a solvent or diluent that is suitable to apply as a coating layer onto the surface of the crucible. Suitable metal species include a metal alkoxide, a metal hydroxide, a metal carbonate, as part of a sol-gel, or a combination of two or more thereof.

In one embodiment, the barium, tantalum, and tungsten species are provided to the coating composition as a metal alkoxide. Suitable alkoxides include, but are not limited to, ethoxide, propoxide, isopropoxide, butoxide, etc. The solvent may be any appropriate solvent that may dilute the metal alkoxides and allow application to the quartz crucible surfaces. For example, the solvent may be an organic solvent, including but not limited to, an ester, an alcohol, a ketone, a hydrocarbon, or a mixed solvent. Suitable alcohols may include, but are not limited to, methanol, ethanol, 1-propanol, 2-propanol, 1-butanol, 2-butanol, iso-butyl alcohol, isopropanol, 1-pentanol, 2-pentanol, 2-methyl-2-pentanol, iso-amyl alcohol, n-propyl alcohol, sec-butyl alcohol, and benzyl alcohol. Suitable solvent ketones include, but are not limited to, acetone, ethylmethylketone, methylsiobutylketone, etc. Suitable hydrocarbons include, but are not limited to, toluene, xylene, hexane, cyclohexane, dichloropropane, chloroform, carbon tetrachloride, chlorotoluene, etc. Further, it may be suitable to use a combination of two or more of these solvents.

In one embodiment, the metal species can be added as the metal hydroxide or oxide. The metal hydroxide can be barium hydroxide and the tantalum compound would be tantalic acid, germanium oxide, tungsten oxide or acid anhydride, tin oxide and or a hydrated tin oxide, or a combination of two or more thereof. In another embodiment, the metal species can be added as a metal carbonate, e.g., barium carbonate, with the tantalum oxide, tungsten oxide, germanium oxide, tin oxide, or a combination of two or more thereof

In another embodiment, the first and second metal components can be provided as part of a composition that forms a gel or film on a surface of the crucible. Such compositions include, for example, sol-gel compositions. In one embodiment, the metal species are incorporated into a coating composition comprising alkyl and/or alkoxy germanes or stannanes, which provides a germane or stannane sol that gels and provides a coating that is partially Ge—O based or Sn—O based and partially organic based.

In addition to providing barium in the alkoxide, hydroxide, or carbonate form, barium may also be added to the coating composition as a barium halide including, but not limited to, BaCl₂, BaF₂, BaBr₂, BaI₂, or any combination thereof

The barium component and the other metal (i.e., tantalum, germanium, tin, or tungsten) component of the devitrification agent may be combined to provide a single composition. The components may be mixed by mechanical agitation, manual agitation, or any other appropriate means of mixing.

The devitrification agent may be applied as a coating layer to the inner and/or outer surfaces of the crucible. The coated area on the surface of the crucible can be on a part or the whole of the inner surface, or can be on a part or the whole of the outer surface, or can be on a part or whole of both the inner and outer surfaces. The coating layer may be applied to a heated crucible, a warmed crucible, a room-temperature crucible, or a chilled crucible. A heated or warmed crucible will provide for evaporation of the solvent of the devitrification agent off of the crucible and will begin leaving deposits of the devitrifying agents. Further, at an ideal temperature, the deposits of the devitrifying agents will not run. A non-limiting example of a suitable coating composition is a composition comprising barium ethoxide and tantalum isopropoxide in ethanol as the solvent. The devitrification agent may be applied at room temperature (e.g. from about 20° C. to about 30° C.). In one embodiment, the coating may be applied from a non aqueous solvent at temps of from 20° C. up to 70° C. or 80° C.

The crucible surface can be coated by any method which deposits the devitrification agent onto the surface, such as paint coating, drip coating, spin coating or spray coating processes. The painting method may include the use of a brush. A crucible may be drip coated by dripping a solvent-based solution of the devitrification agent onto the surface and decanting off the solvent after the devitrification agent has adhered to the crucible surface. The devitrification agent may be dripped onto the surface of the crucible as the crucible is rotated to distribute the solution evenly across the surface. The devitrification agent may react with the crucible and/or the air and may precipitate onto the crucible surface as the solvent and any soluble impurities evaporate away or are decanted off of the crucible.

The drip coating method is suitable when treating the interior surface of a crucible because most of the impurities in the solvent of the devitrification agent are decanted off and do not adhere to the crucible surface.

Another method for coating a crucible surface involves spraying a heated crucible to adhere the devitrification agent to the crucible surface. In a one spray coating method, argon gas and the devitrification agent described above are simultaneously sprayed onto a crucible that has been heated to about 80 to 100° C. The devitrification agent immediately adheres to the crucible surface and is converted to deposits upon contact with any moisture in the air.

Additionally, the spray coating method is suitable for coating the exterior of the crucible. Slight heating of the crucible provides better adherence of the devitrification agent and quicker drying. Spray coatings are generally not meant to be applied as a continuous film. Rather they are typically employed to be applied as a surface seeding for the growth of devitrification. As such they can be locally applied at selected areas with bare uncoated spaces in between the locally covered spots. Application of the coating in this manner does not diminish the efficiency of the devitrification step.

After applying the devitrification agent on the surface of the crucible, the crucible is dried and then is ready to be used in a crystal growth process. No baking of the applied coating needs to be done.

After coating the crucible with a coating layer of devitrification agent, the crucible may then be used in a Cz process, where the crucible is filled with polysilicon and heated to melt the polysilicon. The devitrification agent creates nucleation sites as the crucible is heated to the melt temperature.

The coating layer must contain sufficient devitrification agent to nucleate a layer of substantially devitrified silica. A concentration of at least 0.025 mMol of metal per thousand square centimeters generally provides a uniform seeding capable of promoting devitrification. If a weaker concentration is used, the nuclei may be too small to grow at a rate exceeding dissolution by the melt. Consequently, the nuclei may dissolve before crystallization occurs, particularly in a large diameter (e.g., 55.88 cm) crucible with a higher temperature melt at the crucible wall. When the interior surface of a crucible is coated, the concentration must be low enough to prevent impurities within the coating composition from contaminating the melt and causing poor minority carrier lifetime and oxygen induced stacking faults. In general, the concentration of Ba alkaline earth metal deposited on the inner surface of the crucible for the present devitrifying agent comprised of the Ba component and the second metal component (tantalum, tungsten, germanium, and/or tin) may be 25% of the surface dosages employed by other conventional surface and bulk doping methods. In addition for the melt doping methods, again the dosage of the Ba plus second metal component (tantalum, tungsten, germanium and/or tin) may be about 25% of the dosages used previously. When the interior of the crucible is coated, the devitrification agent most preferably has a segregation coefficient less than 2.25×10⁻⁸, indicating that the concentration of impurities within a grown crystal will be less than 0.05 parts per trillion atomic (2.5×10⁹/cm³).

Regarding the quartz glass crucible having a coated layer of devitrification agent on its inside surface, the cristobalite layer is formed uniformly on its inside surface by the crystallization accelerating action of the devitrification agent when the crucible is heated during pulling up of the single crystal. As the result, the dislocation free ratio of the pulled crystal is increased. Moreover, regarding the quartz glass crucible having a coated layer on its outside surface, since the crystallinity at the peripheral wall of said crucible is increased by cristobalite formation, the strength of the crucible at high temperature heating is increased, so that the deformation of the crucible can be prevented.

In one embodiment, the devitrification agent may include barium alkoxide which may become unstable as the crucible is heated and may convert to barium oxide which readily reacts with silica on the crucible surface to form barium silicate. The barium may decompose at about 300° C. and create nucleation sites when the crucible is heated to about 800 to 1000° C. Crystallization may occur at the nucleation sites as the silicate is heated, and may continue throughout the crystal growth process, forming a ceramic shell on the crucible surface.

When the exterior of the crucible is coated, the segregation coefficient of the devitrification agent is insignificant because impurities on the crucible exterior generally do not affect the purity of the silicon single crystal.

The surface-treated crucibles of the present technology are prepared by applying a coating containing the devitrification agent to a surface of a conventional fused quartz crucible. Any fused quartz crucible that can be used in a Cz process can be surface-treated in accordance with the present technology. Suitable crucibles are commercially available from manufacturers including General Electric Company, Momentive Quartz and Silicones and Toshiba Ceramics, or can be manufactured according to known methods. Many commercially available crucibles have been treated to reduce the alkali metal concentration in the crucible. However, some of the crucibles have sodium, potassium and other alkali metals concentrated on their outer surfaces because of incomplete removal during treatment. Alkali metals are preferably removed from the outside surface of a crucible before an external coating is applied to the crucible. If the alkali metals are not removed prior to applying the coating, the devitrified shell formed in accordance with the present technology may be separated from the crucible by the formation of a layer of low melting alkali silicates.

### Melt Doping

In one embodiment, the devitrification agent may be added to the silicon melt from a crucible through a process of melt doping. In accordance with the present technology, it has been discovered that the amount of contaminants released into a silicon melt from a crucible during a crystal growing process may be reduced by doping the silicon melt with a devitrification agent that is capable of causing devitrification of the silica crucible surface. The reaction path for the formation of the devitrified layer may avoid porosity and island undercutting from decomposition products that can become trapped in the devitrified layer. Furthermore, the formation of the devitrified layer relative to the various stages involved in crystal growth is such that at critical points during ingot growth the surface may allow for release of insoluble gases from the walls of the crucible resulting in fewer crystal voids and reduced particulate generation.

During the melting of the polysilicon of the present technology and throughout the ingot growth process within a silica crucible, the devitrification agent contained in the silicon melt may interact with the silica crucible and may provide nucleation sites at the crucible surface where stable crystal seed nuclei form and may cause the vitreous silica at the crucible surface to crystallize and form a substantially uniform and continuous devitrified shell of cristobalite on the surface of the crucible.

The metal can be introduced into the silicon melt in any suitable species. Generally, if adding the devitrification agent to the silicon melt, it is desirable not to introduce any organic species into the melt. Therefore, when doping the silicon melt, the barium and tantalum, tungsten, germanium and/or tin can be added as the metal itself, a metal oxide, a metal hydroxide, or an alloy compound.

In one embodiment, the introduction of a devitrification agent into the silicon melt to prepare the doped silicon melt in a crucible is facilitated by adding a devitrification agent alloyed with polysilicon in solid form to a silica crucible. As used herein, the term “alloy” or “alloyed” refers to a substance composed of two or more metals (an “intermetallic” compound), one metal with a metal compound, or two metal compounds. The alloy can be an alloy of any two metals of interest, a silicon doped alloy of one or more metals of interest, or combinations thereof. For example, in one embodiment, the alloy can be an alloy of barium and one or more metals of interest. In another embodiment, the metal can be silicon doped with barium and/or tantalum, tungsten, germanium, and/or tin. Of course, combinations of two or more alloy materials may be added to the silicon melt. The make up of the alloy and the amount of alloy materials used can be selected to provide the desired ratio of barium to the other metals.

In one embodiment, a barium/silicon alloy and a silicon alloy of tantalum, tungsten, germanium, and/or tin may be utilized in a devitrification agent. At lower concentrations of barium in the barium/silicon alloy the barium is substantially dissolved into the silicon matrix and substantially no direct chemical reaction between the barium and silicon occurs. As the amount of barium in the barium/silicon alloy increases, the dissolution limit of barium in silicon is reached and barium/silicon chemical compounds such as BaSi₂ and BaSi may be formed in the alloy. Therefore, at higher concentrations of barium the barium/silicon alloy may be comprised of two components: dissolved barium in silicon and barium/silicon chemical compounds. Similarly, at lower concentrations of tantalum, tungsten, germanium, and/or tin in the silicon doped alloy the metal is substantially dissolved into the silicon matrix and substantially no direct chemical reaction between the tantalum and silicon occurs. As the amount of metal in the metal/silicon alloy increases, the dissolution limit of the metal in silicon is reached and metal/silicon chemical compounds such as, for example, TaSi₂ and TaSi may be formed in the alloy. Therefore, at higher concentrations of metal the metal/silicon alloy may be comprised of two components: dissolved metal in silicon and metal/silicon chemical compounds.

A substantially uniform and continuous devitrified shell forms on the inside surface of the crucible up to the melt line and is continuously regenerated as the melt dissolves the shell throughout the ingot growing process. The substantially uniform and continuous devitrified shell formed on the inner surface of the crucible dissolves substantially uniformly when in contact with the silicon melt. Dislocations formed in a growing crystal are thus minimized as a substantial amount of particulates are not released into the melt by the devitrified shell or are released as much finer particulates that will dissolve quickly and be fully dissolved before they can get close to the growing crystal. Further the finer particulate will be released in a more control manner than would large particulate.

The continuous layer of devitrified silica formed due to the interaction of barium and tantalum with the silica surface may not immediately be formed upon the heating and melting of the doped polysilicon. After the devitrification agent and polysilicon are charged to the crucible and melting begins, the devitrification agent may begin to cause the inside surface in contact with the melt to devitrify. Because devitrification of the crucible is not instantaneous upon the heating of the devitrification agent, gases such as argon which are insoluble in silicon contained in the crucible matrix may escape from the crucible surface and leave the melt prior to incorporation into the growing ingot as void defects. After the devitrification agent doped silicon is charged to a silica crucible and melted causing a devitrified layer to form on the crucible surface, a single silicon crystal may grow. Several methods of growing crystals are well known in the art.

As discussed above, the barium source and the tantalum, tungsten, germanium and/or tin sources may be used as components of the devitrification agent added to the silicon melt to promote devitrification of the silica surface during polysilicon melting and during the growing of the single silicon ingot. The devitrification agent of the present technology is utilized such that substantial incorporation of barium into the body of the growing crystal is significantly reduced and crystal properties such as oxygen induced stacking faults, point defect clusters, minority carrier lifetime and gate oxide integrity exhibit only minor effects. It is preferred that no more than about 5 ppbw, no more than about 3 ppbw, or even no more that about 2 ppbw are incorporated into the body of the growing crystal.

Alloys for use in the present technology may be prepared using, for example, an induction melting furnace. Granular, chunk, or a mixture of granular and chunk polysilicon may be first loaded into and melted within the furnace at a suitable temperature. Once the temperature of the molten polysilicon equilibrates a suitable amount of devitrification agent may be added to the molten silicon. The silicon/devitrification agent mixture may be agitated and mixed. Finally, the heat may be removed and the mixture allowed to solidify to create a devitrification agent-polysilicon alloy in accordance with the present technology for use in growing a single crystal silicon ingot. Subsequently, the alloyed polysilicon may be charged directly into a silica crucible for melting, or may be mixed with some amount of virgin polysilicon to properly adjust the amount of devitrification agent entering the melt to control devitrification of the silica surface.

In another alternative embodiment, the preparation of the devitrification doped alloy may be prepared in a Czochralski furnace. Granular, chunk, or a mixture of granular and chunk polysilicon may be first loaded into and melted within the furnace at a suitable temperature. Once the temperature of the molten polysilicon equilibrates a suitable amount of devitrification agent may be added to the molten silicon. The silicon/devitrification agent mixture may be agitated and mixed. Finally, the heat may be removed and the mixture allowed to solidify to create a devitrification agent-polysilicon alloy in accordance with the present technology for use in growing a single crystal silicon ingot. Subsequently, the alloyed polysilicon may be charged directly into a silica crucible for melting, or may be mixed with some amount of virgin polysilicon to properly adjust the amount of devitrification agent entering the melt to control devitrification of the silica surface.

In yet another alternative embodiment, the preparation of the devitrification agent doped molten silicon of the present technology may be accomplished through the addition of devitrification agent directly into a crucible containing melted polysilicon. In this embodiment chunk, granular, or a mixture of chunk and granular polysilicon may be first melted within a crucible located in the crystal growing apparatus. After the temperature of the melted silicon in the crucible has equilibrated, devitrification agent is added directly into the melted silicon, and then the melt is stirred using the Accelerated Crucible Rotation Technique to fully mix the devitrification agent dopant with the molten silicon, and subsequently the ingot growing process is initiated. Alternatively, polysilicon and devitrification agent may be added simultaneously and then melted together. These embodiments cause the devitrified layer of silica on the crucible to form later in the melt down and stabilization prior to the crystal growing process than the alloy-type doping described above. For the same doping level, alloy-type doping may result in faster devitrification of the silica surface as the devitrification agent is present throughout the silicon melting process allowing devitrification to begin earlier. Doping after the silicon is melted results in later start to the devitrification of the silica as it takes additional time for the devitrification agent to be mixed with the polysilicon and reach the silica surface.

The amount of devitrification agent to be alloyed with polysilicon and melted or added directly to melted polysilicon in the crystal growing apparatus prior to ingot growth should be such that a thin, continuous layer of devitrified silica forms on the crucible wall in contact with the doped molten silicon. A thin, continuous layer of devitrified silica allows stresses in the layer to be equally distributed throughout the entire layer resulting in a substantially crack-free surface. This continuous layer allows for void release from the crucible surface due to the kinetic rate of formation during the crystal growth, and thus reduces the incorporation of void defects into the growing ingot. The amount of devitrification agent in the molten silicon necessary to produce a thin, continuous, crack-free surface will vary depending upon the size of the crucible. The present technology is useful in creating a devitrified layer with all crucible sizes, including but not limited to 14 inch to 32 inch crucibles. Also, single or double chambered crucibles are within the scope to the present technology. The amount of devitrification agent necessary to achieve devitrification is a function of the pulling process utilized and the construction and configuration of the hot zone. Hot zones are generally characterized as either “conventional” hot zones or “advanced” hot zones. Conventional hot zones have typically been utilized at temperatures of between about 50 and about 150° C. hotter than advanced hot zones. Advanced hot zones are generally better insulated and use purge tubes such that the temperatures need not be as high as conventional hot zones.

The amount of devitrification agent necessary to create sufficient devitrification is determined based upon the volume of the silicon charge, wetted area of the crucible surface, and type of hot zone utilized.

It will be recognized by one skilled in the art that a controlled devitrification layer thickness can be readily achieved by varying the amount of barium compound added. Variables such as charge composition, pulling technique and apparatus, and pulling time may require that a thicker or thinner devitrified layer be used to achieve the benefits of the present technology.

### Silica Crucible Doping

The devitrification agent may also be provided to dope the crucible itself with the desired materials. The crucible can be doped throughout the bulk of the crucible structure or doped to provide a greater concentration of devitrification agent near the surface of the crucible. In one embodiment, the metal may be added in with the silica sand that is fused into the crucible during production. The materials can be added as a metal oxide, e.g., barium oxide, tantalum oxide, tungsten oxide, germanium oxide, and/or tin oxide.

One aspect of the present technology provides a silica glass crucible comprising an innermost devitrification agent-doped layer to promote devitrification and an intermediate layer that is thick enough for prolonged operation and is free of bubbles near the inner surface and has reduced bubble growth. The crucible may further comprise a stable outer layer that may show little swelling during multiple ingot pulls.

The intermediate layer may be bubble-free (“BF”) and exhibit reduced bubble-growth (“NBG”) and may be at least 1 mm or more thick, or 2 mm or more thick, or in some cases where the bulk is doped to greater depth even 3 mm or more thick. The devitrification agent -doped inner layer or surface may be less than about 1.0 mm thick, less than about 0.7 mm thick, even less than about 0.6 mm thick.

A silica glass crucible according to this aspect of the technology may be formed by introducing bulk silica grain, comprising essentially quartz grain, into a rotating crucible mold. The bulk silica grain may be crystalline grains of natural quartz, cleaned by means known to those working in the field. The grains may be filled into a mold that rotates about its longitudinal axis. The formed grain may then be heated to fuse a crucible.

After the innermost surface of the formed grain fuses, the devitrification agent-doped grain may be introduced and melted as it travels toward the fused innermost surface thus creating a devitrification agent -doped layer that may be fused to the innermost surface of the formed grain.

The devitrification techniques discussed above shall now be explained in the following with reference to embodiments:

### EXAMPLES

The effects of a devitrification promoter are evaluated using bar sag tests with quartz/fused silica bars. Known quantities of devitrification agent were applied onto the surface of a quartz/fused silica bar. The fused silica bar was then put into a furnace for a bar sag test. When the bar was uncoated, it sagged as a viscous compound in a normal bar sag test. The bar was measured after the test to enable the calculation of the viscous sag effects at the plateau temperature.

When a devitrification agent was applied to the bar, some degree of devitrification may occur. When there is sufficient devitrification over the surface, the devitrified layer acts as an “exoskeleton” to the bar and effectively stiffens it against the effects of gravity in the sag test. Thus, for a variation of doses applied, the “effective sag” was measured. The effective sag was measured and mathematically treated like a viscous sag. The devitrification on a sample shows that the sample is no longer purely a viscous material, and therefore that the sag is no longer purely “viscous sag.” When there was enough devitrification on the surface or throughout the bulk, the fused silica bar is reinforced and reduced or eliminated resultant effective sag. The “effective sag” was calculated based on the method of bar sag defined by F. T. Trouton, F. R. S., On the Coefficient of Viscous traction and Its Relation to that of Viscosity, Proceedings of the Royal Society of London. Series A, Containing Papers of a Mathematical and Physical Character. Vol. 77, No. 519, (May 14, 1906) pp 426-440 (Published by the Royal Society), and refined by using modern statistical analysis to improve the fit and further refine coefficients for the equation.

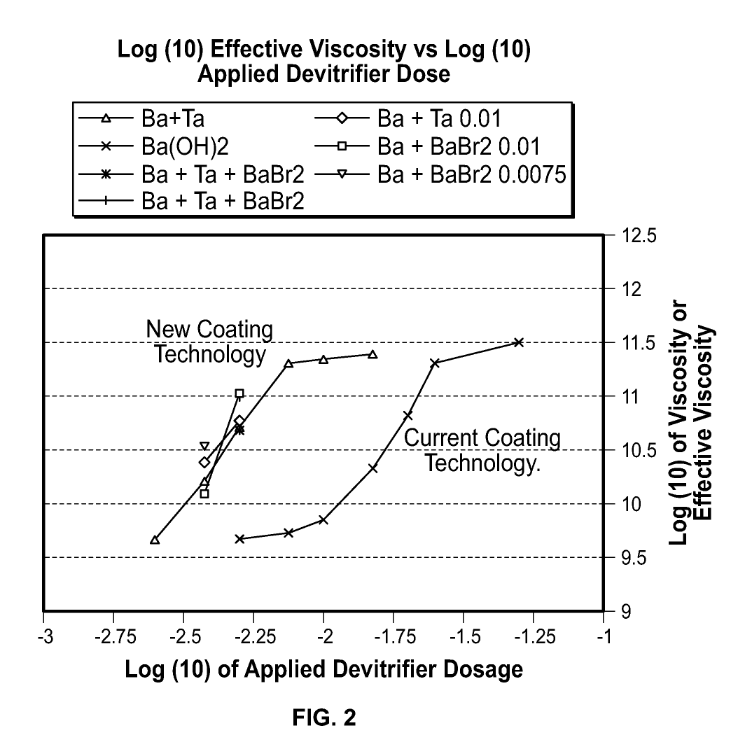

Bar sags were completed at 1500° C., 1525° C., and 1550° C. for 6, 12, and more than 12 hours. The bar sags were then used calculate an effective viscosity or effective sag resistance based on Trouton's rule. FIG. 2 shows the separation of the effective sag resistance versus applied dose for the new test compound versus the older existing compound. The y-coordinate is Log (10) of viscosity, and the x-coordinate is log (10) of dosage of devitrification agent applied. The right hand curve is the “effective viscosity” or sag resistance obtained from the standard existing devitrification agent of Ba(CO)₃ at a range of dosages from the upper right at the standard dosage applied to the typical product today, To lower dosages at the lower left of that RH Curve. The left hand curve is the viscosity obtained from the newer devitrification agents (BaO+Ta₂O₅) applied in the stoichiometry of BaO:Ta₂O₅ of 6:1. The curve graphically demonstrates that the new agents cause a quartz sample to exhibit higher “effective viscosity” or sag resistance when compared to the same dose of Ba applied to the surface of the Bars being tested.

The devitrification promoter in accordance with aspects of the invention are shown to be more efficient than prior barium systems and exhibit more sag resistance for the same amount of compound or similar effective sag at lower loadings.

Embodiments of the technology have been described above and modifications and alterations may occur to others upon the reading and understanding of this specification. The claims as follows are intended to include all modifications and alterations insofar as they come within the scope of the claims or the equivalent thereof

The listing of claims replaces all previous versions of the claims:

1. A crucible comprising a body of vitreous silica having a bottom wall and a sidewall extending up from the bottom wall and defining a cavity for holding the molten silicon material, the sidewall formation and the bottom wall each having an inner and an outer surface, the crucible comprising a devitrification agent comprising (a) a first metal chosen from barium and (b) a second metal chosen from tantalum, tungsten, germanium, tin, or a combination of two or more thereof.

2. The crucible of claim 1, wherein the devitrification agent has a ratio of first metal to second metal of from about 1:1 to about 10:1.

3. The crucible of claim 1, wherein devitrification agent has a ratio of first metal to second metal of from about 2:1 to about 8:1.

4. The crucible of claim 1, wherein devitrification agent has a ratio of first metal to second metal of from about 5:2 to about 6:1.

5. The crucible of any of claim 1, wherein the devitrification agent is disposed as a coating on at least a portion of a surface of the crucible.

6. The crucible of claim 5, wherein the coating comprises the first metal in the form of an alkoxide, a hydroxide, a carbonate, a sol-gel solution, or a combination of two or more thereof, and the second metal in the form an alkoxide, a hydroxide, an acid, an oxide, a carbonate, a sol-gel solution, or a combination of two or more thereof.

7. The crucible of claim 6, where the devitrification agent further comprises a barium halide.

8. The crucible of any of claim 1, wherein the devitrification agent is disposed in the crucible body.

9. The crucible of claim 8, wherein the devitrification agent comprises (a) barium oxide, and (b) tantalum oxide, tungsten oxide, germanium oxide, tin oxide, or a combination of two or more thereof.

10. A method for preparing a silicon melt for pulling a single crystal comprising:
providing silicon to a crucible comprising a body of vitreous silica having a bottom wall and a sidewall extending up from the bottom wall and defining a cavity for holding the molten silicon material, the sidewall formation and the bottom wall each having an inner and an outer surface, the crucible comprising a devitrification agent comprising (a) a first metal chosen from barium and (b) a second metal chosen from tantalum, tungsten, germanium, tin, or a combination of two or more thereof; and
melting the silicon within the crucible to form a first layer of substantially devitrified silica on the inner surface of the crucible which is in contact with the molten silicon.

11. The method of claim 10, wherein the devitrification agent has a ratio of first metal to second metal of from about 1:1 to about 10:1.

12. The method of claim 10, wherein devitrification agent has a ratio of first metal to second metal of from about 2:1 to about 8:1.

13. The method of claim 10, wherein devitrification agent has a ratio of first metal to second metal of from about 5:2 to about 6:1.

14. The method of claim 10, wherein the devitrification agent is disposed as a coating on at least a portion of a surface of the crucible.

15. The method of claim 14, wherein the coating comprises the first metal in the form of an alkoxide, a hydroxide, a carbonate, a sol-gel solution, or a combination of two or more thereof, and the second metal in the form an alkoxide, an acid, an oxide, a hydroxide, a carbonate, a sol-gel solution, or a combination of two or more thereof.

16. The method of claim 1, where the devitrification agent further comprises a barium halide.

17. The method of claim 10, wherein the devitrification agent is disposed in the silicon melt.

18. The method of claim 17, wherein the devitrification agent comprises (a) barium oxide, barium metal, an alloy compound comprising barium, or a combination of two or more thereof, and (b) the second metal in the form of a metal oxide, metal compound, an alloy compound comprising the second metal, or a combination of two or more thereof.

19. The method of claim 10, wherein the devitrification agent is disposed in the crucible body.

20. The method of claim 19, wherein the devitrification agent comprises (a) barium oxide, and (b) tantalum oxide, tungsten oxide, germanium oxide, tin oxide, or a combination of two or more thereof.
